(19) United States
(12) Patent Application Publication
(10) Pub. No.: US 2013/0134519 A1
(43) Pub. Date: May 30, 2013

(54) SEMICONDUCTOR DEVICE

(71) Applicant: Panasonic Corporation, Osaka (JP)

(72) Inventor: NAOHISA SENGOKU, Toyama (JP)

(73) Assignee: PANASONIC CORPORATION, Osaka (JP)

(21) Appl. No.: 13/751,217

(22) Filed: Jan. 28, 2013

Related U.S. Application Data
(63) Continuation of application No. PCT/JP2011/004254, filed on Jul. 27, 2011.

(30) Foreign Application Priority Data
Dec. 22, 2010 (JP) 2010-285912

(51) Int. Cl. H01L 29/78

(52) U.S. Cl. CPC H01L 29/78
USPC 257/364

(57) ABSTRACT

A semiconductor device includes a conductive film formed on an insulating film, and a first polysilicon film formed on the conductive film. A stacked film including the conductive film and the first polysilicon film forms a first pattern including a central region, and end regions each located at a side of the central region. A silicide film is formed on at least the central region of the stacked film. A discontinuity is formed in a central region of the conductive film. The conductive film is separated into the two portions by the discontinuity.

### CROSS-REFERENCE TO RELATED APPLICATIONS

This is a continuation of International Application No. PCT/JP2011/004254 filed on Jul. 27, 2011, which claims priority to Japanese Patent Application No. 2010-285912 filed on Dec. 22, 2010. The entire disclosures of these applications are incorporated by reference herein.

### BACKGROUND

The present disclosure relates to semiconductor devices, and more particularly, to semiconductor devices which improve characteristics of fuse elements.

Fuses have been widely used in complementary metal oxide semiconductor (CMOS) integrated circuits to permanently store information, or to form permanent connections on the circuits. In general fuses, a passivation film is intentionally removed to provide a space for a fuse material in order to avoid destroying neighboring devices when the fuse is blown.

As a technique of improving such fuses, a fuse including a polysilicon film and a silicide film has been proposed (Japanese Translation of PCT International Application No. H11-512879). FIGS. 10A and 10B respectively show a schematic cross-sectional view and a schematic plan view of such a fuse (the line Xa-Xa′ of FIG. 10B corresponds to FIG. 10A).

In other words, the fuse includes an insulating film 11 formed on a silicon substrate 10, a polysilicon film 12 formed on the insulating film 11, and a silicide film 13 formed on the polysilicon film 12. Sidewall spacers 14 are formed on side surfaces of the polysilicon film 12 and the silicide film 13, and an interlayer film 15 is formed on the silicon substrate 10 including the fuse. A contact 16 is formed in the interlayer film 15 to reach the silicide film 13, whereby a wiring 17 on the interlayer film 15 and the fuse are electrically connected together. As shown in FIG. 10B, the fuse has a planar shape so that the central region thereof is narrower than each of end regions thereof.

If a predetermined programming voltage is applied to the silicide film 13 through the contact 16, as shown in FIG. 10C, agglomeration occurs in the silicide to form an electrical discontinuity 18. If a small amount of dopant is added in the polysilicon film 12, the discontinuity of the silicide film 13 can increase a resistance (electric resistance) between both terminals. This structure can provide a small fuse which can be produced at low cost by using a CMOS process. The fuse further has characteristics of in which, for example, the fuse can be blown at a low voltage, the fuse can be programmed without damage to the overlying insulating film, the passivation film does not have to be removed, etc., resulting in contributing to easy formation of elements and reduction of fabrication cost.

### SUMMARY

However, the fuse described above has the following problems.

In recent years, a structure of using a high-k film as a gate insulating film, and using a metal electrode has been developed. That is because the use of a high-k film as a gate insulating film makes it possible to make an equivalent oxide thickness (EOT) thinner while maintaining a large physical thickness and avoiding an increase in gate leakage current. That is also because the use of a metal electrode makes it possible to prevent depletion of a gate electrode.

FIG. 10D illustrates a case where the above fuse is applied to a metal inserted poly-Si stack (MIPS) structure that is a structure formed by stacking a polysilicon film on a metal film. This is a structure obtained by inserting a metal layer 19 between the insulating film 11 and the polysilicon film 12 in the structure of FIG. 10A.

When the above fuse is utilized in such a MIPS structure, the resistance value cannot sufficiently increase even if the fuse is blown. That is because, in the fuse having a MIPS structure, in addition to the polysilicon film 12 and the silicide film 13, the lowermost metal layer 19 which adjusts the work function of a metal gate is also associated with the resistance (conductivity) between terminals. In other words, even if the silicide film 13 is blown, there exists the polysilicon film 12 and the lowermost metal layer 19 having a low resistance value, and therefore, the resistance value of the blown fuse does not sufficiently increase.

Another problem is caused when both of a fuse and an antifuse are needed as elements in a circuit. In order to provide such a circuit, it is necessary to mount the fuse and the antifuse separately, thereby causing an increase in the occupying area of the fuse and that of the antifuse in a chip, an increase in the number of processing steps, etc.

In view of the above problems, it is an object of the present disclosure to provide a semiconductor device, and a method of fabricating such a device, the device including a fuse and an antifuse each of which can sufficiently change the resistance value even if the device has a MIPS structure.

A method of fabricating a semiconductor device in the present disclosure includes steps of: (a) forming a first insulating film on a substrate; (b) forming a conductive film on the first insulating film; (c) forming a first polysilicon film on the conductive film; (d) patterning a stacked film including the conductive film and the first polysilicon film to form a first pattern including a central region, and end regions each located at a side of the central region; and (e) forming a silicide film on at least the central region of the stacked film, wherein the method further comprises, after the step (b) and before the step (c), the step (f) of removing part of the conductive film in a region which is to be the central region to form a discontinuity.

In the step (d), a width of the central region may be narrower than that of each of the end regions.

The step (f) may not be performed.

With such steps, the semiconductor device which can be used as a fuse, and an antifuse (element whose resistance decreases doe to conduction). The semiconductor device will be described later.

The method in the present disclosure may further include, after the step (d) and before the step (e), the steps of: (g) introducing an impurity into at least part of the first polysilicon film in each of the end regions to change the at least part of the first polysilicon film to be a second polysilicon film; and (h) forming a second insulating film in each of two regions each located between the central region and each of the end regions of the stacked film, in the step (e), a silicide film is formed on each of at least the central region, and the end regions of the stacked film which are separated by the second insulating film, and the method further comprises, after the step (e), the step (i) of forming a contact so that the contact is connected to the silicide film on each of the at least the central region, and the end regions.

With such steps, the electric connection of each of the end regions to the conductive film and the electric connection of the silicide film on the central region can be achieved.

A resistivity of the second polysilicon film may be lower than that of the first polysilicon film.

With such a feature, the silicide film and the conductive film are electrically connected together in the end region.

The method may further include, after the step (a) and before the step (b), the step of forming a gate insulating film on the first insulating film.

In the step (d), the stacked film may be patterned, thereby forming a gate electrode in addition to the first pattern, and in the step (e), a silicide film may be formed on the gate electrode of the stacked film.

With such a feature, the structure which serves as a fuse, and an antifuse can be formed at the same time as the step of forming a metal gate electrode having a MIPS structure. In other words, the increase in the number of fabricating steps can be reduced.

A resistivity of the first polysilicon film may be 0.01 Ωcm or more.

As an example of the resistivity of the first polysilicon film, the resistivity of the first polysilicon film may have such a value.

A composition ratio of silicon to a metal in the silicide film may be less than 2.

It is preferable to form the silicide film in which the composition ratio of silicon to the metal is relatively small in order to allow the silicide film to become silicon-rich in response to the polysilicon film with heating, and the composition ratio is, for example, less than 2.

The silicide film may include at least one of Ti, Co, Ni, Pt, Mo or W.

The silicide film may include at least one of Ni₃ Si, Ni₃₁Si₁₂, Ni₂Si, Ni₃Si₂ or NiSi.

Specific materials of the silicide film can include such examples.

Next, in order to attain the above object, a first semiconductor device in the present disclosure includes: a conductive film formed on an insulating film; and a first polysilicon film formed on the conductive film, wherein a stacked film including the conductive film and the first polysilicon film forms a first pattern including a central region, and end regions each located at a side of the central region, a silicide film is formed on at least the central region of the stacked film, a discontinuity is formed in a central region of the conductive film, and the conductive film is separated into two portions by the discontinuity.

Such a semiconductor device can change the resistance between the end regions sandwiching the discontinuity by allowing current to flow through the silicide film to cause heating, and the identical element can be used as a fuse and an antifuse.

If current in a predetermined range is allowed to flow through the silicide film, a composition ratio of silicon to a metal in the silicide film may increase, and the silicide film may expand to become a silicon-rich silicide film, and the silicon-rich silicide film may connect the two portions of the conductive film separated by the discontinuity.

In other words, if current in a predetermined range is allowed to flow through the silicide film, the silicide film on the central region is heated by overcurrent. By the heating, the silicide film on the central region becomes silicon-rich (a composition ratio of silicon to the metal increases), and in particular, it expands downward (toward the first polysilicon film). As a result, the two portions of the conductive film separated by the discontinuity are connected through the silicon-rich silicide film, whereby the resistance between the end regions decreases. In this way, current flow through the silicide film can change the resistance value from a very high state to a low state, and the device can be used a so-called antifuse.

Further, if current over the predetermined range is allowed to flow through the expanded silicide film, agglomeration and discontinuity or discontinuity may occur in the film.

With such a feature, current in a predetermined range is allowed to flow through the silicide film, whereby the resistance between the end regions decreases, and the device can be used as an antifuse, as stated above. Then, if current over the predetermined range is allowed to flow through the silicide film, the silicide film connecting the two separated portions of the conductive film agglomerates to cause discontinuity, whereby the resistance between the end regions increases to be in the high state, again. Therefore, the device can be used as a fuse.

The silicide film may be separated into at least three portions to be formed on the central region and the end regions, in each of the end regions, a second polysilicon film may be formed between the silicide film and the conductive film, and a resistivity of the second polysilicon film may be lower than that of the first polysilicon film, and in the central region, the discontinuity may be located under the silicide film.

With such a structure, each of the end regions at both sides of the discontinuity is electrically connected to the conductive film, and by utilizing the silicide film above the discontinuity, the device can function as an antifuse and a fuse.

Next, a second semiconductor device in the present disclosure includes a conductive film formed on an insulating film; and a first polysilicon film formed on the conductive film, wherein a stacked film including the conductive film and the first polysilicon film forms a first pattern including a central region, and end regions each located at a side of the central region, a silicide film is separated into at least three portions to be formed on the central region and the end regions of the stacked film, and in each of the end regions, the first polysilicon film between the silicide film, and the conductive film serves as a second polysilicon film having a lower resistivity than that of the first polysilicon film.

If current in a predetermined range is allowed to flow through the silicide film, a composition ratio of silicon to a metal in the silicide film may increase, and the silicide film may expand to become a silicon-rich silicide film, and the silicon-rich silicide film may be in contact with the conductive film.

The second semiconductor device can change the resistance between the end regions sandwiching the central region by allowing current to flow through the silicide film to cause heating, and can be used as an antifuse.

In other words, if current in a predetermined range is allowed to flow through the silicide film, the silicide film on the central region is heated by overcurrent. By the heating, the silicide film on the central region becomes silicon-rich (a composition ratio of silicon to the metal increases), and in particular, it expands downward (toward the first polysilicon film). As a result, when the silicon-rich silicide film reaches the conductive film, the silicide film in addition to the conductive film contributes to the conduction between the end regions, whereby the resistance between the end regions decreases. The second semiconductor device serves as an antifuse.

Further, if current over the predetermined range is allowed to flow through the expanded silicide film, agglomeration and discontinuity may occur in the silicide film.

With such a structure, after allowing the device to serve as an antifuse, if current over the predetermined range is allowed to flow, agglomerates and discontinuity occur in the silicide film having contributed to the conduction between the end regions, whereby the resistance between the terminals is changed to be in a very high state. Therefore, the device can be used as a fuse.

A width of the central region may be narrower than that of each of the end regions.

With such a feature, when current is allowed to flow through the silicide film, the current density of the current is high in the central region, and therefore, overheating is likely to be caused, and the silicide film is likely to become silicon-rich, and agglomeration and discontinuity are likely to occur in the silicide film.

The second semiconductor device are used as an antifuse, and a fuse, and besides, it can also be used as a device having two interconnect layers in which a conductor film and a silicide film can be independently used as an interconnect. As a result, the structure can be simplified, e.g., the number of interconnect layers can be reduced.

In the first and second semiconductor devices, a resistivity of the second polysilicon film may be 1 Ωcm or less.

A resistivity of the first polysilicon film may be 0.01 Ωcm or more.

As an example of the resistivities of the first and second polysilicon films, the resistivities of the first and second polysilicon films may have such values.

A gate electrode which is a stacked film having an identical structure with the stacked film may be further formed, and the silicide film may be formed on the gate electrode.

In this way, the device may have a metal gate electrode having a MIPS structure, and a fuse (antifuse).

A composition ratio of silicon to a metal in the silicide film may be less than 2.

It is preferable to form the silicide film in which the composition ratio of silicon to the metal is relatively small in order to allow the silicide film to become silicon-rich in response to the polysilicon film with heating, and the composition ratio is, for example, less than 2.

The silicide film may include at least one of Ti, Co, Ni, Pt, Mo or W.

The silicide film may include at least one of Ni₃ Si, Ni₃₁Si₁₂, Ni₂ Si, Ni₃ Si₂ or NiSi.

Specific materials of the silicide film can include such examples.

According to the semiconductor device and the method for fabricating the same in the present disclosure, even if the device has a metal gate electrode having a MIPS structure, current is allowed to flow through the silicide film to cause heating, thereby allowing the silicide film to become silicon-rich and expand or be blown, and the resistance between the end regions can be sufficiently changed. Therefore, the device can be used as an antifuse, and a fuse.

### BRIEF DESCRIPTION OF THE DRAWINGS

FIGS. 1A and 1B are respectively a cross-sectional view and a plan view (only some of elements) which schematically illustrate an example semiconductor device in a first embodiment of the present disclosure.

FIGS. 2A and 2B are views illustrating the operation of the example semiconductor device in the first embodiment.

FIGS. 3A-3E are views illustrating a method of fabricating the example semiconductor device in the first embodiment.

FIGS. 4A-4E are views illustrating the method of fabricating the example semiconductor device in the first embodiment after FIG. 3E.

FIGS. 5A and 5B are respectively a cross-sectional view and a plan view (only some of elements) which schematically and illustrate an example semiconductor device in a second embodiment of the present disclosure.

FIGS. 6A and 6B are views illustrating the operation of the example semiconductor device in the second embodiment.

FIGS. 7A-7D are views illustrating a method of fabricating the example semiconductor device in the second embodiment.

FIGS. 8A-8E are views illustrating the method of fabricating the example semiconductor device in the second embodiment after FIG. 7D.

FIG. 9A is a view illustrating a case of a structure in the second embodiment where a metal gate serves as two interconnect layers, and FIG. 9B is a view illustrating a comparative example in which a metal gate in prior art is used as one single interconnect layer.

FIGS. 10A-10D are views illustrating a conventional fuse.

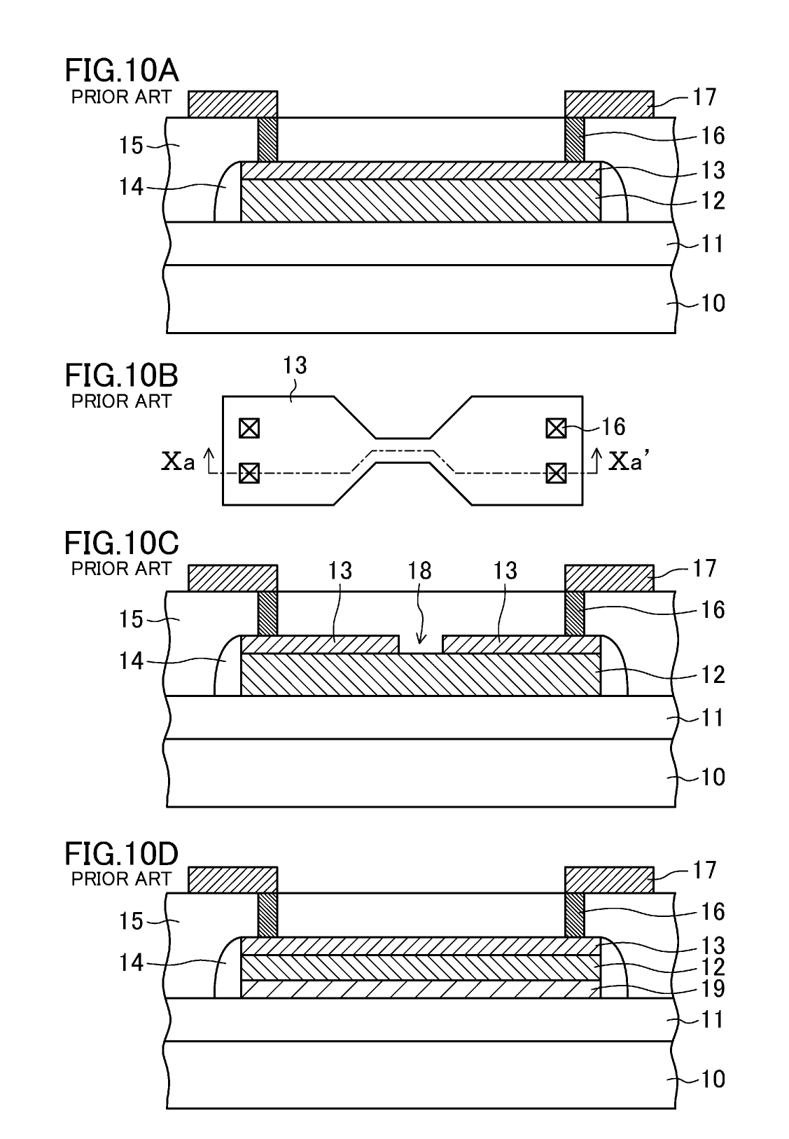

### DETAILED DESCRIPTION

### First Embodiment

An example semiconductor device in a first embodiment of the present disclosure and a method of fabricating the same will be described hereinafter.

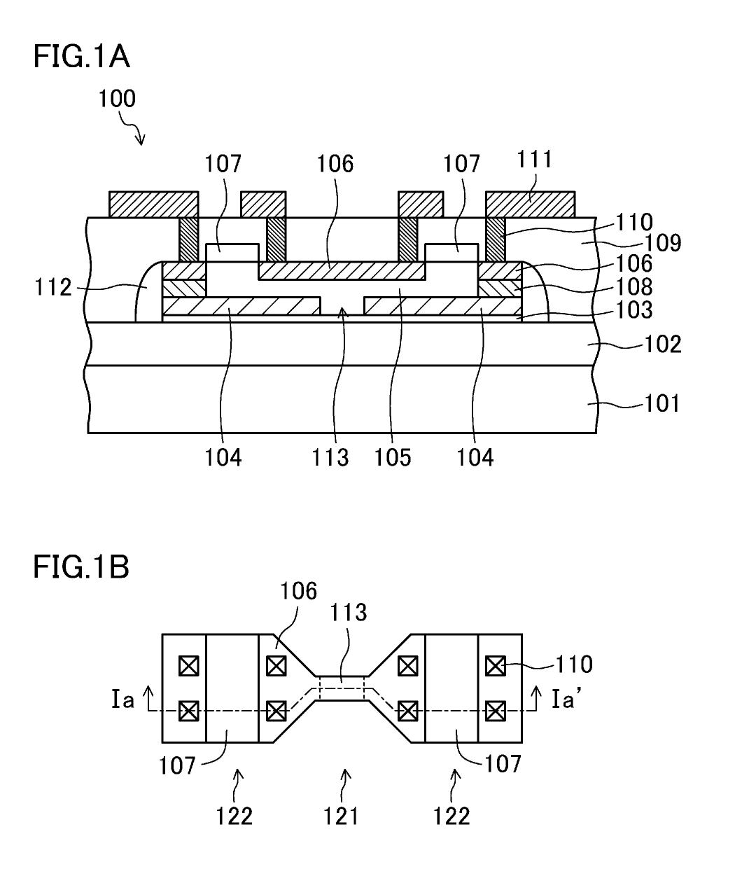

FIGS. 1A and 1B are respectively a cross-sectional view and a plan view which schematically illustrate an example semiconductor device 100. The cross section taken along the line Ia-Ia′ of FIG. 1B corresponds to FIG. 1A. FIG. 1B illustrates only some of the elements shown in FIG. 1A.

The semiconductor device 100 is a device including as a fuse (serves an antifuse, too), and is formed by using a silicon substrate 101. A first insulating film 102 serving as, e.g., a shallow trench isolation (STI), and a gate insulating film 103 made of HfO₂ etc. are stacked on the silicon substrate 101.

On the gate insulating film 103, a metal film 104 made of a TiN film, a TaN film, a TaCNO film, etc., is formed as a conductive film, where a discontinuity 113 is formed in the central region thereof. A first polysilicon film 105 is formed to cover the discontinuity 113 and the metal film 104. The first polysilicon film 105 is made of an undoped polysilicon film, or a doped silicon film having a small dose amount (for example, 1×10¹⁸ cm⁻² or less), and therefore, it has a very high resistance. For example, the resistivity of the first polysilicon film 105 is 0.01 Ωcm or more.

On the first polysilicon film 105, a first silicide film 106 made of NiSi etc. is formed. The first silicide film 106 is not formed in a portion in which a silicide blocking film 107 is formed on the first polysilicon film 105, and is separated into three portions, i.e., the central portion, and end portions located at both sides of the central portion. The silicide blocking film 107 is made of an O₃-TEOS film etc., and has a function of physically inhibiting a silicide reaction.

The metal film 104, the first polysilicon film 105, and the first silicide film 106 constitute a fuse. As shown in the plan view of FIG. 1B, the fuse has a planar shape so that a width of a central region 121 thereof is narrower than that of end regions 122 located at both sides of the central region 121. Each of transitional regions which is located between the central region 121 and the end region 122 and whose width is changed is tapered by an angle of about 45° (by an angle of 45° with respect to parallel sides of the region whose width is constant when viewed in plan) toward the central region 121 from the end region 122.

In each of the end regions 122, a second polysilicon film 108 having a resistance value lower than the first polysilicon film 105 is formed between the first silicide film 106 and the metal film 104. For example, the resistivity of the second polysilicon film 108 is 1 Ωcm or less. The second polysilicon film 108 is formed by implanting impurities into the first polysilicon film 105 at the same time with, e.g., a source/drain (S/D) implantation step.

Sidewall spacers 112 are formed at both side surfaces of the fuse. The fuse, the silicide blocking film 107, the sidewall spacer 112, etc., are covered with an interlayer insulating film 109. Contacts 110 (contact plugs) passing through the interlayer insulating film 109 are formed on the first silicide film 106 formed on each of the end region 122 and the central regions 121. Moreover, the contact 110 is connected to a wiring 111 made of Cu etc. on the interlayer insulating film 109.

In each of the end regions 122, the wiring 111, the contact 110, the first silicide film 106, the second polysilicon film 108, and the metal film 104 are electrically connected together, and the electrical connection between the end regions 122 is disconnected in the discontinuity 113 in the central region 121. If the metal film 104 is continuously formed (in other words, no discontinuity 113 is formed) in the central region 121, the end regions 122 are electrically connected together.

In the first silicide film 106 on the central region 121, at least two contacts 110 are provided to sandwich a portion over the discontinuity 113, and the wiring 111, the contact 110, the first silicide film 106, the contact 110, and the wiring 111 are electrically connected together. Terminals of each of the end regions 122 (the wirings 111 etc.) and terminals of the central region 121 are practically insulated from one another by the first polysilicon film 105 having a very high resistance.

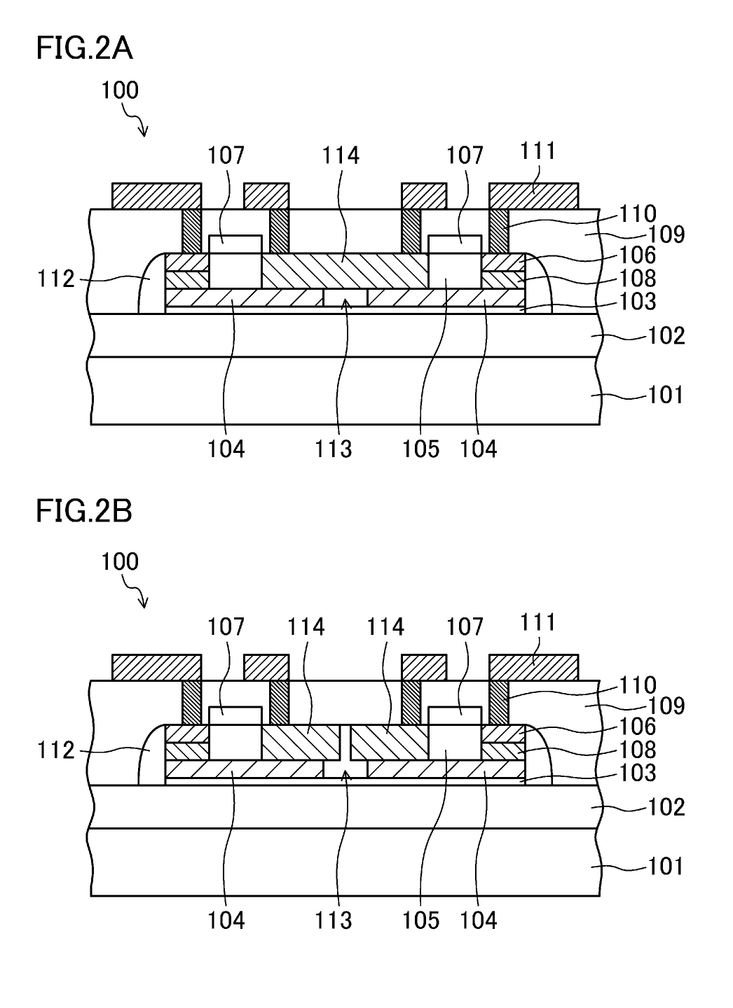

Next, an operation method of the fuse (the antifuse) described above will be described with reference to FIGS. 2A and 2B.

First, with reference to FIG. 2A, by utilizing the terminals of the central region 121 (the wirings 111 located in the central region 121 to sandwich the portion over the discontinuity 113), a case of allowing current in a predetermined range (equal to or more than a first threshold value and equal to or less than a second threshold value) to flow through the first silicide film 106 in the central region 121 is assumed. In this case, the current density of the current having reached the first silicide film 106 from the wiring 111 through the contact 110 becomes higher in the central region 121 whose width is narrower, resulting in overheating the first silicide film 106 due to the over current. As a result, because of the reaction between the first silicide film 106 and the first polysilicon film 105 located thereunder, the first silicide film 106 becomes silicon-rich (a composition ratio of silicon to the metal increases, for example, NiSi is changed to NiSi₂), and the volume of the first silicide film 106 expands, whereby the silicide film 106 becomes a second silicide film 114 contacting the metal film 104.

In this way, the end regions 122 having been insulated from each other due to the existence of the discontinuity 113 are electrically connected together through the second silicide film 114. In other words, the resistance value is changed from a very high state to a low state. Accordingly, the semiconductor device 100 serves as a so-called antifuse.

The first threshold value is a current amount necessary to allow the first silicide film 106 to become silicon-rich, and the second threshold value is a current amount necessary to cause agglomeration and discontinuity of the silicide film, as described below.

Next, with reference to FIG. 2B, a case of allowing current having a value more than the second threshold value to flow through the space between the terminals of the central region 121 in the semiconductor device 100 in the state shown in FIG. 1A is assumed.

In this case, the first silicide film 106 becomes the silicon-rich second silicide film 114 by heating, and is further overheated to cause agglomeration and discontinuity of silicide. In this process, though the end regions 122 are electrically connected together through the second silicide film 114 and may be in a low resistance state, it is finally returned to be in a high resistance state which causes discontinuity, as shown in FIG. 2B.

The device can be also used as the fuse as shown in FIG. 2B with the current having a value more than the second threshold value after it is used as the antifuse as shown in FIG. 2B with the current in a range from the first threshold value to the second threshold value. Applications of the device make it possible to use the device as a writable and erasable memory. In other words, information can be stored by utilizing the change of the resistance value between the end regions 122, and the information can be written and erased since the device serves as the fuse and the antifuse.

As described above, the resistance value between the end regions 122 can be changed from a high resistance state to a low resistance state, and then can be changed from the low resistance state to a high resistance state. Therefore, according to the semiconductor device 100, the identical pattern can be used as the antifuse and the fuse.

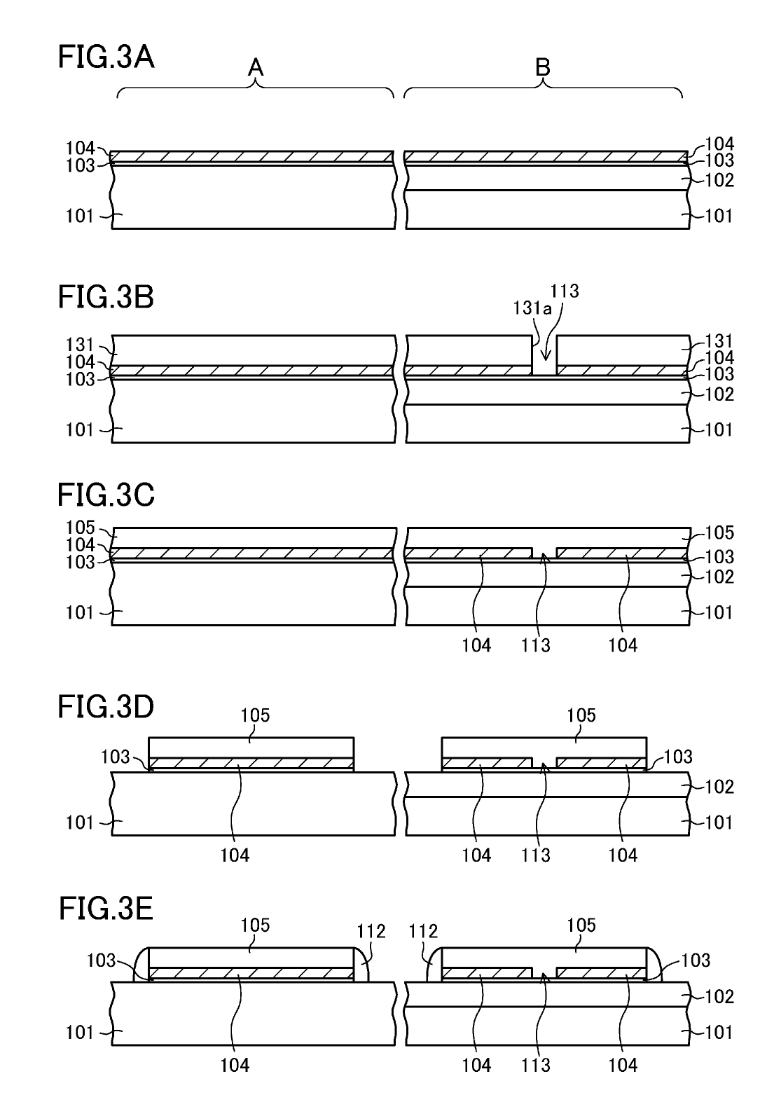

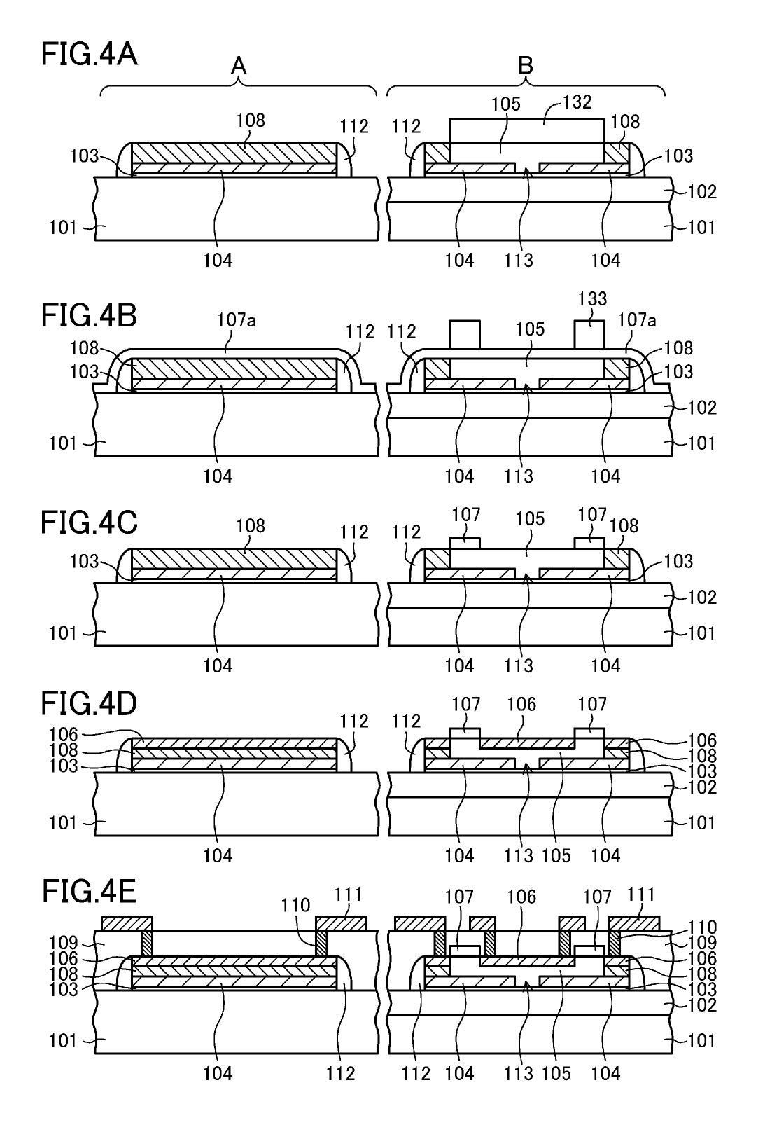

Next, a method of fabricating the semiconductor device 100 will be described with reference to FIGS. 3A-3E, and 4A-4E. The step of forming the structure of the fuse shown in FIGS. 1A and 1B can be consistent with the step for forming a metal gate electrode in a MIPS structure. In other words, the metal gate electrode in the MIPS structure and the fuse in the embodiment can be formed on the identical substrate by the same step.

The steps of the method will be sequentially described hereinafter from the step of FIG. 3A, assuming that a transistor is formed in region A, and the fuse (antifuse) is formed in region B.

In the step of FIG. 3A, first, the first insulating film 102 serving as, e.g., a shallow trench isolation (STI) is formed on the silicon substrate 101. This film is formed in the vicinity of the region A as an isolation of elements, and in the region B as a portion constituting the fuse.

Next, an oxide film (so-called IL, i.e., inter layer) having a thickness of approximately 1 nm, which is not shown, is formed in the region A and the region B, and then, the gate insulating film 103 which is a HfO₂ film is formed to have a thickness of approximately 2.0 nm. Then, the metal film 104 made of TiN is formed on the gate insulating film 103 to have a thickness of approximately 10 nm as a gate metal layer having a function of modulating the work function of the gate electrode.

Next, in the step of FIG. 3B, a resist 131 is formed on the metal film 104 by using a photolithography technique etc. An opening 131a is formed in the resist 131 in the region B. Then, the metal film 104 located under the opening 131a is removed using a chemical solution, such as sulfuric acid/hydrogen peroxide mixture (SPM), to provide a discontinuity 113. Thereafter, the resist 131 is removed.

Next, in the step of FIG. 3C, the first polysilicon film 105 having a thickness of approximately 40 nm is formed to cover the metal film 104. This film is formed as an undoped polysilicon film, for example.

Next, in the step of FIG. 3D, the first polysilicon film 105, the metal film 104, and the gate insulating film 103 are patterned. To perform the patterning, a predetermined resist pattern (not shown) is formed on the first polysilicon film 105, and then, the first polysilicon film 105 and the metal film 104 are patterned by dry etching using the predetermined pattern as a mask. Thereafter, the resist pattern is removed, and subsequently, the exposed part of the gate insulating film 103 is also removed.

With these steps, the respective films are shaped so that in the region A, the films for forming the gate electrode have a rectangular shape, and in the region B, the films forming the fuse have a planer shape shown in FIG. 1B.

Next, in the step of FIG. 3E, extension implantation is performed (not shown). Then, etch back is performed after a SiN film etc. is formed, thereby forming the sidewall spacers 112 at the side surfaces of the gate electrode in the region A and the sidewall spacers 112 at the side surfaces of the fuse in the region B.

Next, the step of FIG. 4A is performed. After a resist pattern 132 is formed by lithography, source/drain (S/D) implantation is performed by using the resist pattern as a mask. At this time, the implantation is performed with respect to the entire surface of the gate electrode in the region A, and end regions of the fuse in the region B. In the region B, a resist 132 is formed to cover the first polysilicon film 105 except the end regions. Subsequently, after the resist is removed, an anneal treatment is performed at a temperature of 1000° C. for 10 seconds to activate the dopant.

In this way, in the gate electrode of the region A, the entirety of the first polysilicon film 105 becomes the second polysilicon film 108, whereby the resistance value (resistivity) decreases. In the fuse of the region B, both of the end portions of the first polysilicon film 105 becomes the second polysilicon film 108, whereby the resistance value thereof decreases. The rest portion (the portion covered with the resist 132) is not changed, and remains to be the undoped first polysilicon film 105.

Next, the step of FIG. 4B is performed. An O₃-TEOS film 107a which is to be changed to be the silicide blocking film 107 is formed on the entire surface to have a thickness of approximately 20 nm. Then, a resist 133 is formed on a predetermined position of the O₃-TEOS film 107a (the position at which the silicide blocking film 107 is to be provided).

Next, the step of FIG. 4C is performed. The exposed part of the O₃-TEOS film 107a is removed by using a wet-etching solution, such as buffered hydrofluoric acid (BHF), with the resist 133 as a mask. With this removal, the silicide blocking film 107 is provided. Then, the resist 133 is removed.

Next, the step of FIG. 4D is performed. After a nickel film (not shown) having a thickness of approximately 10 nm, an anneal treatment is performed at a temperature of, e.g., 260° C. for, e.g., 30 seconds to allow the nickel film to react with the first polysilicon film 105 or the second polysilicon film 108 to form a Ni₂Si film. Subsequently, the film is cleaned by using a cleaning solution, such as SPM, to remove an extra part of the nickel film. Then, an anneal treatment is performed at a temperature of, e.g., 450° C. for, e.g., 30 seconds to change the Ni₂Si film to a NiSi film, thereby obtaining the first silicide film 106.

The first silicide film 106 is not formed in a region in which the silicide blocking film 107 is formed.

Next, the step of FIG. 4E is performed. First, linear SiN (not shown) having a thickness of approximately 20 nm is formed on the entire surface, and then, an O₃-TEOS film having a thickness of approximately 300 nm is formed. Thereafter, the surface is planarized by chemical mechanical polishing (CMP) to form the interlayer insulating film 109.

Subsequently, contact holes are formed at predetermined positions by contact lithography. The contact holes are buried with a TiN film and a W film, and then, extra part of the films is removed by CMP to obtain the contacts 110. Thereafter, the wiring 111 made of Cu etc. is formed to be connected to each of the contacts 110.

In this way, the fuse of the embodiment can be formed by utilizing the steps for forming the gate electrode in the MIPS structure. Therefore, a CMOS including the metal gate electrode and the fuse of the embodiment can be simultaneously formed.

The first polysilicon film 105 is the undoped polysilicon film, and instead of this film, the first polysilicon film 105 may be a doped silicon film having a small dose amount (for example, 1×10¹⁸ cm⁻² or less).

As a metal used for the first silicide film 106, Ti, Co, Pt, Mo, W, etc., may be used instead of Ni. The film becomes silicon-rich by current flow, and therefore, it is preferable to form a silicide film in which a composition ratio of silicon to the metal is relatively small, for example, less than 2. As the silicide film in which Ni is included, Ni₃Si, Ni₃₁Si₁₂, Ni₂Si, Ni₃Si₂, NiSi, etc., can be used.

### Second Embodiment

An example semiconductor device in a second embodiment of the present disclosure and a method of fabricating the same will be described hereinafter.

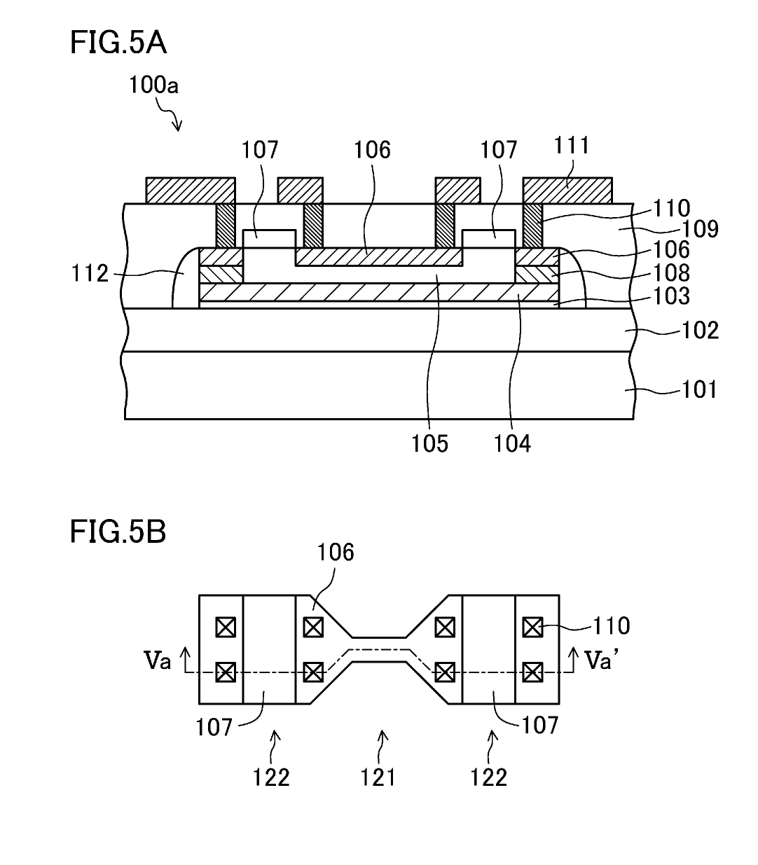

FIGS. 5A and 5B are respectively a cross-sectional view and a plan view which schematically illustrate an example semiconductor device 100a. The cross section taken along the line Va-Va′ of FIG. 5B corresponds to FIG. 5A. FIG. 5B illustrates only some of the elements shown in FIG. 5A.

The semiconductor device 100a of the embodiment has the same structure as the semiconductor device 100 shown in FIGS. 1A and 1B except not including a discontinuity 113. In other words, the metal film 104 is continuously formed in the central region 121 and both of the end regions 122. Therefore, the end regions of the fuse are electrically connected together through the wiring 111, the contact 110, the first silicide film 106, the second polysilicon film 108, the metal film 104, the second polysilicon film 108, the first silicide film 106, the contact 110, and the wiring 111. The first polysilicon film 105 has a very high resistance, and only the metal film contributes to the conduction in the central region 121, and therefore, the electric resistance is relatively high.

Other than above structure, the semiconductor device 100a has the same structure as the semiconductor device 100 described in the first embodiment. In particular, in the central region 121, the wiring 111, the contact 110, the first silicide film 106, the contact 110, and the wiring 111 are electrically connected together. The terminals of the end regions 122 (the wirings 111 etc.) and the terminals of the central region 121 are practically insulated from one another by the first polysilicon film 105 whose resistance is very high.

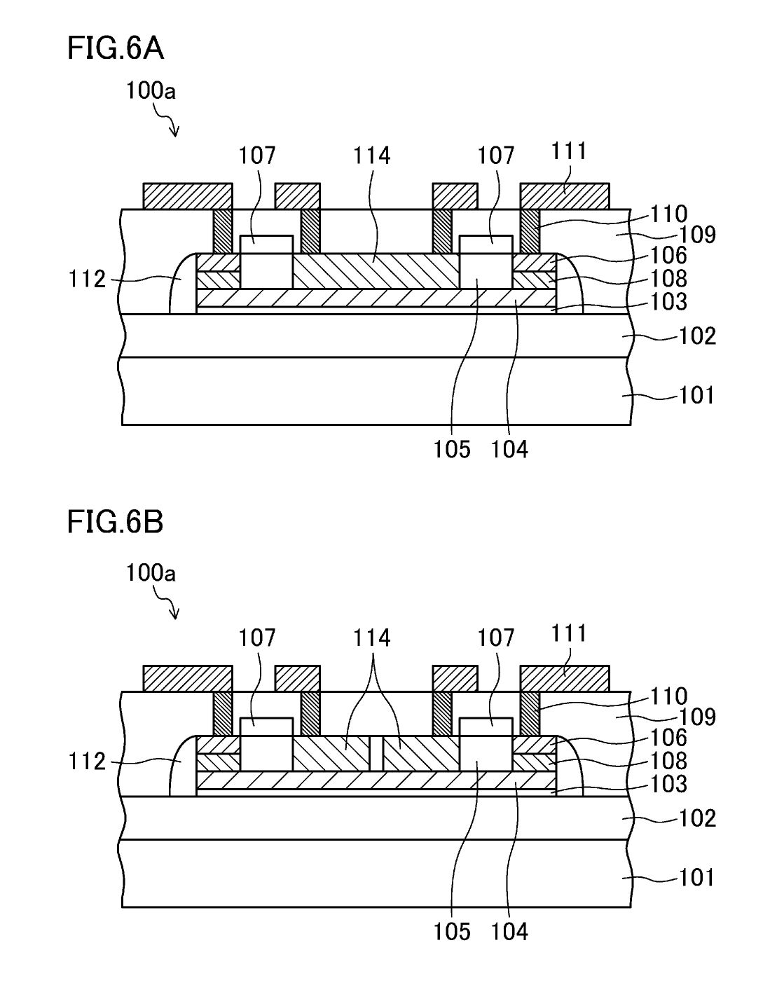

Next, an operation method of the fuse described above will be described with reference to FIG. 6A.

A case of allowing current in a predetermined range (equal to or more than a first threshold value and equal to or less than a second threshold value) to flow through the first silicide film 106 in the central region 121 is assumed by utilizing the wirings 111. In this case, the current density of the current having reached the first silicide film 106 from the wiring 111 through the contact 110 becomes higher in the central region 121 whose width is narrower, resulting in overheating the first silicide film 106 due to the over current. As a result, because of the reaction between the first silicide film 106 and the first polysilicon film 105 located thereunder, the first silicide film 106 becomes silicon-rich (for example, NiSi is changed to NiSi₂), and the volume of the first silicide film 106 expands, whereby the silicide film 106 becomes a second silicide film 114 contacting the metal film 104.

With this change, in addition to the metal film 104, the second silicide film 114 contributes to the conduction between the end regions 122. In other words, a high resistance state shown in FIG. 5A since current is conducted through only the metal film 104 is transitioned to a low resistance state shown in FIG. 6A since current is conducted through the metal film 104 and the second silicide film 114. Therefore, the semiconductor device 100a serves as a so-called antifuse.

If current having a value more than the second threshold value is allowed to flow through the second silicide film 114, the second silicide film 114 agglomerates, as shown in FIG. 6B, to be changed to be in a high resistance state again. In other words, the device serves as a fuse.

As described above, the resistance value between the end regions 122 can be changed from a high resistance state to a low resistance state, and then can be changed from the low resistance state to the high resistance state, again. Therefore, according to the semiconductor device 100a, the identical pattern can be used as the antifuse and the fuse.

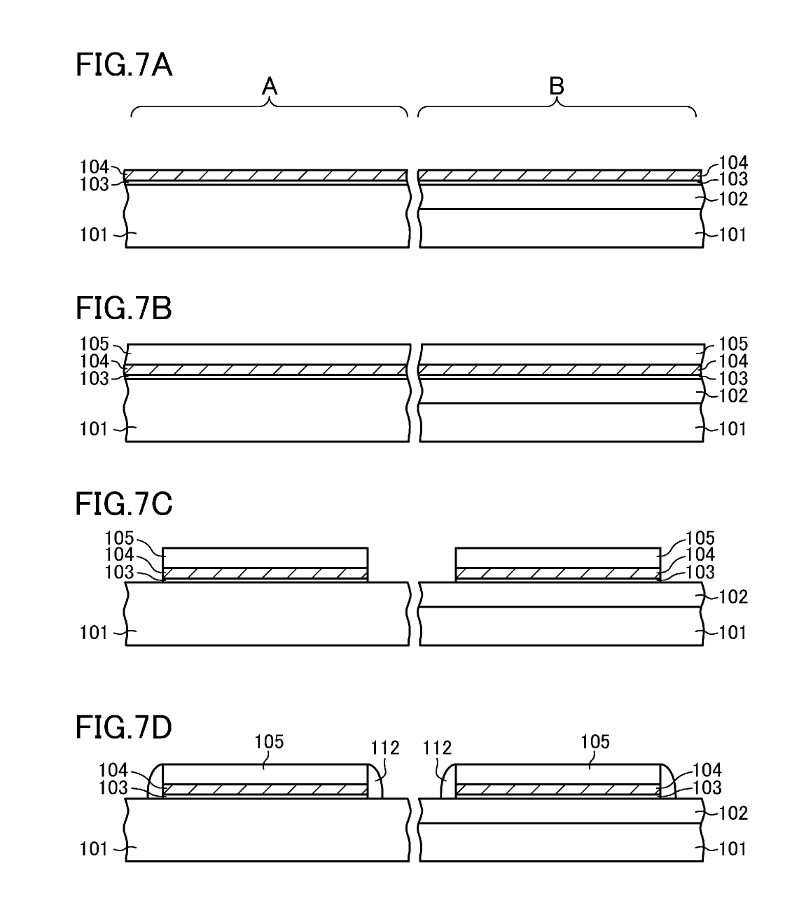

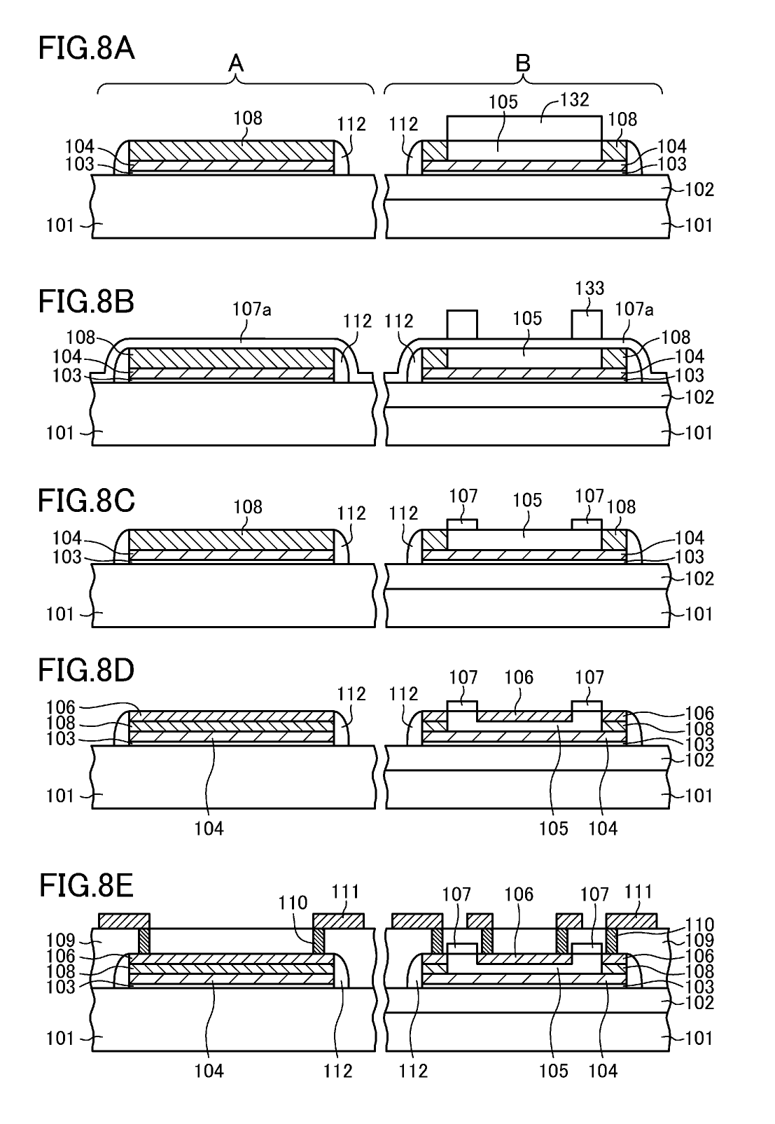

Next, a method of the semiconductor device 100a will be described with reference to FIGS. 7A-7D and 8A-8E.

The semiconductor device 100a can be fabricated not by forming the discontinuity 113 shown in FIG. 3B in the method of fabricating the semiconductor device 100 of the first embodiment.

Specifically, in the step of FIG. 7A, as well as FIG. 3A, the first insulating film 102, IL (not shown), the gate insulating film 103, and the metal film 104 are formed on the silicon substrate 101.

Next, without forming the discontinuity 113 shown in FIG. 3B, in other words, the step of FIG. 7B is performed with the metal film 104 continuously formed in the region B for forming the fuse. In FIG. 7B, as well as FIG. 3C, the first polysilicon film 105 is formed on the metal film 104.

Subsequently, in FIG. 7C, as well as FIG. 3D, the metal gate electrode and the fuse are patterned. In FIG. 7D, as well as FIG. 3E, extension implantation is performed and the sidewall spacers 112 are formed.

Subsequently, the respective steps of FIGS. 8A-8D are performed in the same manner as those of FIGS. 4A-4D to fabricate the semiconductor device 100a shown in FIGS. 5A and 5B.

In this way, the fuse of the embodiment can be formed by utilizing the steps for forming the gate electrode in the MIPS structure. Therefore, a CMOS including the metal gate electrode and the fuse of the embodiment can be simultaneously formed.

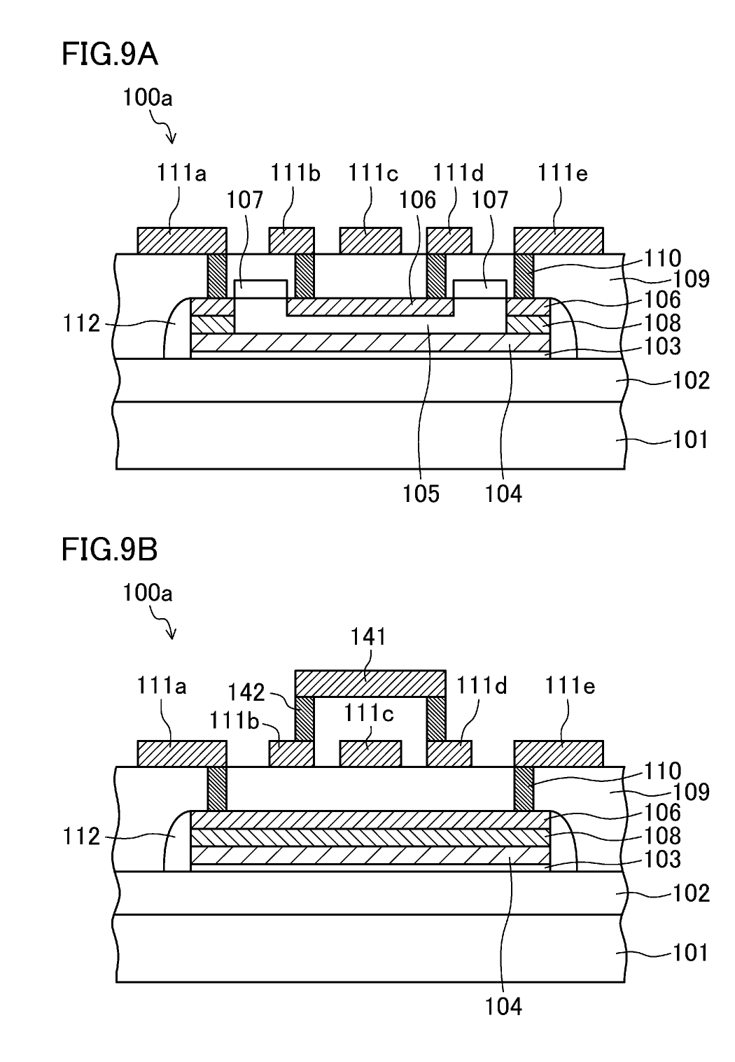

In the semiconductor device 100a, the metal electrode which generally electrically serves one interconnect layer can be used as two interconnect layers. This feature will be described with reference to FIGS. 9A and 9B.

FIG. 9A illustrates a structure obtained by adding a wiring on the interlayer insulating film 109 in the semiconductor device 100a shown in FIG. 5A. In other words, in the semiconductor device 100a, wirings of the wirings 111 connected to the end regions 122 are assumed as wirings 111a and 111e, and wirings of the wirings 111 connected to the central region 121 are assumed as wirings 111b and 111d. A wiring 111c is further provided between the wiring 111b and the wiring 111d.

The first silicide film 106 is separated into three portions each located in the two end regions 122 and the central region 121. The first silicide film 106 and the metal film 104 in the central region 121 are practically insulated from each other by the first polysilicon film 105 (an undoped polysilicon film or a doped polysilicon film having a small dose amount). With this structure, the first silicide film 106 formed in the upper part of the fuse can be used in order to electrically connect the wiring 111b and the wiring 111d together while avoiding the electric connection with the wiring 111c. At the same time, the wiring 111a and the wiring 111e can be electrically connected together by using the metal film 104. In this way, the structure of the fuse of the present disclosure can be used as two interconnect layers.

If the first silicide film 106 is used as an interconnect, the width of the central region 121 does not have to be narrower than that of the end region 122. In other words, the central region 121 and the end region 122 may have the same width, and may have a rectangular planar shape as a whole.

In contrast, FIG. 9B illustrates a structure of a metal gate electrode formed on the entire surface of the second polysilicon film 108, where the first silicide film 106 is not separated, as a comparative example. In this case, in order to provide an electric connection between the wiring 111a and the wiring 111e, and an electric connection between the wiring 111b and the wiring 111d, it is necessary to provide another contact 142 for connecting the wiring 111d etc. to another wiring layer 141 located above the wiring 111d etc.

In this way, according to the semiconductor device 100a of the embodiment, the structure including the metal film 104, the first polysilicon film 105 and the first silicide film 106 which is separately formed can be used as two interconnect layers, thereby making it possible to simplify the structure, such as reducing the number of the interconnect layers. This advantage can reduce fabrication costs, reduce a turn around time (TAT), etc.

As described above, according to the semiconductor device and the method of fabricating the same in the present disclosure, the resistance in the MIPS structure can be sufficiently changed, and the number of the fabrication steps can be reduced, and therefore, the semiconductor device of the present disclosure is useful as a fuse and an antifuse.

What is claimed is:

1. A semiconductor device, comprising:
a conductive film formed on an insulating film; and
a first polysilicon film formed on the conductive film, wherein
a stacked film including the conductive film and the first polysilicon film forms a first pattern including a central region, and end regions each located at a side of the central region,
a silicide film is formed on at least the central region of the stacked film,
a discontinuity is formed in a central region of the conductive film, and
the conductive film is separated into the two portions by the discontinuity.

2. The device of claim 1, wherein
if current in a predetermined range is allowed to flow through the silicide film, a composition ratio of silicon to a metal in the silicide film increases, and the silicide film expands to become a silicon-rich silicide film, and
the silicon-rich silicide film connects two portions of the conductive film separated by the discontinuity.

3. The device of claim 2, wherein
if current over the predetermined range is allowed to flow through the silicon-rich silicide film, agglomeration and discontinuity occur in the silicon-rich silicide film.

4. The device of claim 1, wherein
the silicide film is separated into at least three portions to be formed on the central region and the end regions,
in each of the end regions, a second polysilicon film is formed between the silicide film and the conductive film, and a resistivity of the second polysilicon film is lower than that of the first polysilicon film, and
in the central region, the discontinuity is located under the silicide film.

5. The device of claim 4, wherein
a resistivity of the second polysilicon film is 1 Ωcm or less.

6. The device of claim 1, wherein
a width of the central region is narrower than that of each of the end regions.

7. The device of claim 1, wherein
a resistivity of the first polysilicon film is 0.01 Ωcm or more.

8. The device of claim 1, wherein
a gate electrode which is a stacked film having an identical structure with the stacked film is further formed, and
the silicide film is formed on the gate electrode.

9. The device of claim 1, wherein
a composition ratio of silicon to a metal in the silicide film is less than 2.

10. The device of claim 1, wherein
the silicide film includes at least one of Ti, Co, Ni, Pt, Mo or W.

11. The device of claim 1, wherein
the silicide film includes at least one of Ni₃Si, Ni₃₁Si₁₂, Ni₂Si, Ni₃Si₂ or NiSi.

12. A semiconductor device, comprising:
a conductive film formed on an insulating film; and
a first polysilicon film formed on the conductive film, wherein
a stacked film including the conductive film and the first polysilicon film forms a first pattern including a central region, and end regions each located at a side of the central region,
a silicide film is separated into at least three portions to be formed on the central region and the end regions of the stacked film, and
in each of the end regions, the first polysilicon film between the silicide film and the conductive film serves as a second polysilicon film having a lower resistivity than that of the first polysilicon film.

13. The device of claim 12, wherein
if current in a predetermined range is allowed to flow through the silicide film, a composition ratio of silicon to a metal in the silicide film increases, and the silicide film expands to become a silicon-rich silicide film, and
the silicon-rich silicide film is in contact with the conductive film.

14. The device of claim 13, wherein
if current over the predetermined range is allowed to flow through the silicon-rich silicide film, agglomeration and discontinuity occur in the silicon-rich silicide film.

15. The device of claim 12, wherein
a width of the central region is narrower than that of each of the end regions.

16. The device of claim 12, wherein
a resistivity of the second polysilicon film is 1 Ωcm or less.

17. The device of claim 12, wherein
a resistivity of the first polysilicon film is 0.01 Ωcm or more.

18. The device of claim 12, wherein
a gate electrode which is a stacked film having an identical structure with the stacked film is further formed, and
the silicide film is formed on the gate electrode.

19. The device of claim 12, wherein
a composition ratio of silicon to a metal in the silicide film is less than 2.

20. The device of claim 12, wherein
the silicide film includes at least one of Ti, Co, Ni, Pt, Mo or W.

21. The device of claim 12, wherein
the silicide film includes at least one of Ni₃Si, Ni₃₁Si₁₂, Ni₂Si, Ni₃Si₂ or NiSi.
